(19) United States
(12) Patent Application Publication
(10) Pub. No.: US 2012/0014082 A1
(43) Pub. Date: Jan. 19, 2012

(54) Variable stiffness screen with pneumatic frame

(76) Inventor: Alex Naksen, Flushing, NY (US)

(21) Appl. No.: 13/135,810

(22) Filed: Jul. 16, 2011

Related U.S. Application Data
(62) Division of application No. 10/921,601, filed on Aug. 19, 2004, now abandoned.

(51) Int. Cl. H05K 7/00

(52) U.S. Cl. 361/807

(57) ABSTRACT

A variable stiffness screen with a pneumatic frame for wearable electronic devices provides a viewable area that can be adjusted by managing the screen's physical properties. The screen incorporates a flexible electronic display, attached to a pneumatic frame, in which the structural properties can be changed from a flexible state to a rigid one to control the stiffness of the display.

This is a continuation claiming the benefit of the prior nonprovisional application No.: 921601 and the disclosure document No.: 526866 under 35 U.S.C. 120

### CROSS-REFERENCE TO RELATED APPLICATIONS

### STATEMENT REGARDING FEDERALLY SPONSORED RESEARCH OR DEVELOPMENT

“Not Applicable”

### REFERENCE TO A SEQUENCE LISTING, A TABLE, OR A COMPUTER PROGRAM LISTING COMPACT DISC APPENDIX

“Not Applicable”

### BACKGROUND OF INVENTION

This invention relates to a display unit and, in particular, to a display unit using a flexible medium, which can be rolled up or folded for compact storage and used in conjunction with electronic communication and processing devices.

Our lives are pervaded by a myriad of various kinds of portable and wearable digital devices, many of which are necessary to operate and use on a daily basis. Being used mostly on the go they have some inherent difficulties not allowing for their operation in a precise, quick and comfortable manner. There is an intrinsic contradiction between the miniaturization of wearable electronic devices accompanied by the increasing flow of visual information and the practically unchanged human abilities to receive this information by eye. Reading anything more than a headline on a screen that is barely larger than an inch square is a rather challenging task for our vision. On the other hand, the pocket computer/smart phones are equipped with rather readable displays, but their sheer bulk and rigid shape become insuperable obstacles in situations when size and a way of carrying matter.

This may become the main hurdle not allowing the full realization of the immensely powerful high-speed “forth generation”, or 4G, cellular systems. In our view, the screen size is a critical factor defining the user's experience in this area of mobile computing and communication. We think there is a better way to deliver visual information without either hurting our vision or making the device uncomfortably bulky and heavy. To satisfy the user's needs, an electronic display has to be big enough to display the necessary amount of information in a way comfortable for the eyes, and, at the same time, it has to be unobtrusively small, when the user doesn't need it.

An attempt to solve this problem based on the conventional solid LCD technology, is presented in U.S. Pat. No. 6,144,550 to Weber et al, which disclosed an inflatable and collapsible segmented screen for portable computers, TV screens and the like. The proposed way to fold the screen is to make it from a few rigid segments connected to each other, and supported by some inflated envelopes placed behind the screen. According to the Abstract this invention's design “provides a screen area of approximately the size of conventional and comparable portable computer monitor screens, and like.”

Indeed, this concept with its internal baffled structure and some external sources of pressurized air is arguably well suited for a tabletop or laptop computer but cannot be applied to a significantly smaller electronic device. The reason is that the sheer balk of this approach does not allow the screen to be miniaturized enough to be used in a variety of compact and ultra compact electronic devices, such as the mobile phone and wrist-worn gadget aka electronic watch.

The currently developing ultra-thin flexible electronic display film technology is the most promising in terms of complying with the requirements of portability and comfort of usage. The flexible display can be of various designs and technological features including OLED, LEP, E-Ink, Flexible LCD and so forth. For instance, the OLED display (Organic or polymer light-emitting diodes) provides a high degree of brightness and a wide viewing angle while consuming less energy than common LCD displays. It is thin (1.5 mm-2.0 mm) and, when organic compound is applied to a flexible insulated substrate (plastic, for instance), the entire screen can be bent without losing its properties. U.S. Pat. No. 5,821,688 to Shanks, et al., which is herein incorporated by reference, discloses a flexible panel display having thin film transistors driving polymer light-emitting diodes.

The display device having an extendible screen is disclosed in U.S. Pat. No. 7,180,665 B2, filed on Jun. 23, 2003, to Daniel et al. This device provides a flexible screen, which can be rolled into a relatively compact form when not being used and unrolled into an extended form for the display of information. The display device may comprise a locking mechanism for locking at least one of the side members in its extended position. An analogous concept was described earlier in our Disclosure Document, titled: Variable Stiffness Screen, number: 526866, filed on Feb. 27, 2003. In some respects the analogues concept was shown earlier in our Disclosure Document, titled: Variable Stiffness Screen, number: 526866, filed on Feb. 27, 2003. The Variable Stiffness Screen with Pneumatic Frame of this Patent Application is essentially a more developed initial concept of aforementioned Disclosure Document.

Summarizing, the important problems associated with either rollable or foldable electronic screen displays can be identified as follows:

a) Miniaturization of wearable electronic devices is limited by the size of an electronic display, which has to be large enough to provide readable visual information. A technologically achievable much greater volume of visual information is also limited by the display size. The great potential of 3G and 4G cellular systems could not be fully realized, due to the relatively small conventional LCD display. The apparent limitation of the display size is the device's body itself.

b) Implementation of the flexible display technology could solve the aforementioned problem. To achieve this, an electronic screen has to be used in at least two working modes. Firstly, it has to be rolled or folded for compact storage, thus reducing the overall size of a particular electronic device. Secondly, it has to be fully opened to display the amount of information associated with either Internet content or a smart phone function. At the same time, the virtue of flexibility, which allows for changing of the display's geometry, becomes a liability, when the flexible screen is in a withdrawn position. In this position the flexible display is structurally unstable not allowing for reading of the displayed information in a quick, precise and comfortable manner.

c) When a foldable screen is supposed to be supported internally, for instance by inflating a structure bonded to the screen, the absence of a built-in actuation means (pumps, valves and so forth) renders the entire system quite inefficient, always dependent on external help.

### BRIEF SUMMARY OF THE INVENTION

Accordingly, it is an object of this invention to solve the problems created by the miniaturization of wearable electronic devices accompanied by the increasing flow of visual information, while the human abilities to receive this information by eye remain practically unchanged. More specifically, it is an object of the present invention to provide a lightweight screen display with a viewable area that can be adjusted depending on the volume of information and, ultimately, on the user's needs.

The variable stiffness screen of this invention makes it possible to change the display size by managing the display's stiffness. The variable stiffness screen incorporates a flexible display attached to a pneumatic frame. The screen can be installed directly into a particular electronic device or encased in an intermediate carrying member, either a flexible sleeve or a rigid cartridge.

The main element of the proposed invention is a pneumatic frame allowing for changing of the screen's stiffness. The screen's frame allows the flexible display to be normally pliable and placed inside either an electronic device or a carrying member and, when actuated, to be firm and rigid due to having a pulled-out working position.

Firstly, the structural transition from flexibility to rigidity is achieved by managing the volume, and respectively, the pressure of the atmospheric air entering the frame. It includes hermetically sealed tubular conduits having substantially flexible, resilient walls. When the system is activated by pressing a built-in miniature pneumatic pump, air enters the structurally arranged conduits behind the display's surface, thus making it firm and stable. To make the screen pliable the air is released to relieve the pressure in the conduits.

Therefore, several objects and advantages of the present invention are:

a) The variable stiffness screen with a pneumatic frame provides an electronic device with a display that can be much bigger than the device itself. The miniaturization of wearable electronic devices is no longer limited by the size of a built-in electronic display. A relatively small electronic device such as a multifunctional electronic watch could incorporate the screen of this invention, allowing for displaying of Internet pages and multimedia applications in a way comfortable for the eyes.

b) The design of the variable stiffness screen allows for combining of two seemingly contradictory features, which an electronic screen, based on the flexible display technology, should possess. The first one is firmness or structural stability for displaying of information and being able to be used as a touch screen. The second one is sufficient flexibility for it to be rolled up or folded for compact storage.

c) The screen's integrally built pneumatic frame makes the display usable in any three-dimensional position in which the user can put it. A flexible display can be used as a universal medium for the whole plethora of cellular phones, multifunctional electronic watches and the like. The user can hold them in any convenient manner according to personal habits and wishes.

d) The process of pulling the display out and making it functional in the withdrawn mode is very simple, consisting of only a single move accompanied by the system's simultaneous actuation. The single-move operation provides the display with the desirable immediate accessibility to information.

e) The screen's frame does not need any external source of energy, uses atmospheric air as the medium and includes all the necessary structural and actuation means, making the screen self-sufficient in various conditions.

d) The screen's frame is adjustable to a variety of the structural features of currently being developed flexible displays. The display's minimal thickness, as well as its stiffness, can vary depending on a particular flexible display technology implementation.

Further objects and advantages will become apparent from a consideration of the ensuing description and drawings.

### BRIEF DESCRIPTION OF THE SEVERAL VIEWS OF THE DRAWING FIGURES

The invention will be more readily understood with reference to the accompanying drawings, wherein:

FIG. 1 shows a front view of a variable stiffness screen with pneumatic frame encased in a flexible sleeve.

FIG. 2 shows a side view of the variable stiffness screen with pneumatic frame encased in a flexible sleeve.

FIG. 3 shows a front view of the variable stiffness screen with pneumatic frame encased in a rigid case.

FIG. 4 shows a side view of the variable stiffness screen with pneumatic frame encased in a rigid case

FIG. 5 shows a front view of the variable stiffness screen of FIG. 1 with a broken out portion of the sleeve.

FIG. 6 shows a rear view of the variable stiffness screen of FIG. 1 with a broken out portion of the sleeve.

FIG. 7 shows a sectional view taken along section line 7-7 of FIG. 6.

FIG. 8 shows a sectional view taken along section line 8-8 of FIG. 6.

FIG. 9 shows an enlarged right upper part of FIG. 6 with a broken out portion of the handle.

FIG. 10 shows an enlarged left upper part of FIG. 6 with a broken out portion of the handle.

FIG. 11 shows a sectional view taken along section line 11-11 of FIG. 10.

FIG. 12 shows the conduits configuration with one central vertical element.

FIG. 13 shows the conduits configuration with one central vertical element and two peripheral vertical elements.

FIG. 14 shows a wafer-like configuration of the conduits.

FIG. 15 shows a honey comb-like configuration of the conduits.

REFERENCE NUMERAL IN DRAWINGS

| | |
|---|---|
| 1 variable stiffness | |
| screen with pneumatic frame | |
| 10 flexible display | |
| 20 flat sleeve | |
| | 21 sleeve's opening |
| 30 case | |
| | 31 case's opening |
| | 32 flat part of the case |
| | 33 cylindrical enclosure of the case |
| 40 winding mechanism | |
| | 41 ribbon cable |
| 100 pneumatic frame | |
| 110 conduits assembly | |
| | 112 inner sheet |
| | 113 groove |
| | 114 outer sheet |
| | 116 conduits |
| 120 handle assembly | |
| | 121 intake tube |
| | 122 intake check valve |
| | 123 adaptor |
| | 124 miniature air pump |
| | 125 adaptor |
| | 126 outlet check valve |
| | 126 outlet check valve |
| | 128 connecting tube |
| 130 release valve | |
| | 132 plunger |
| | 133 coil spring |
| | 134 fitting |
| | 135 aperture |

### DETAILED DESCRIPTION OF THE INVENTION

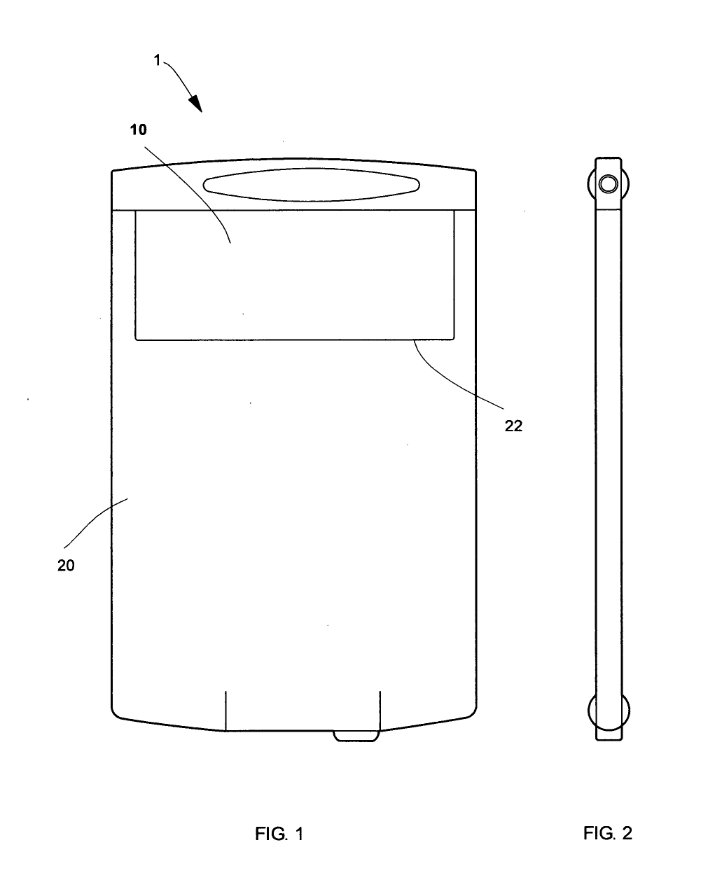

Variable Stiffness Screen with Pneumatic Frame, FIGS. 1-15

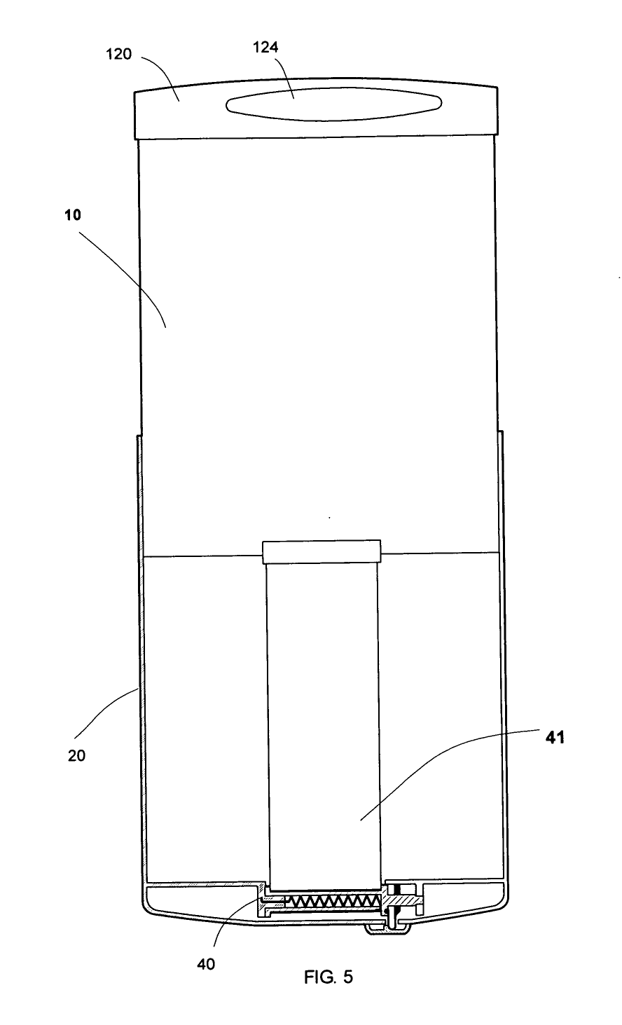

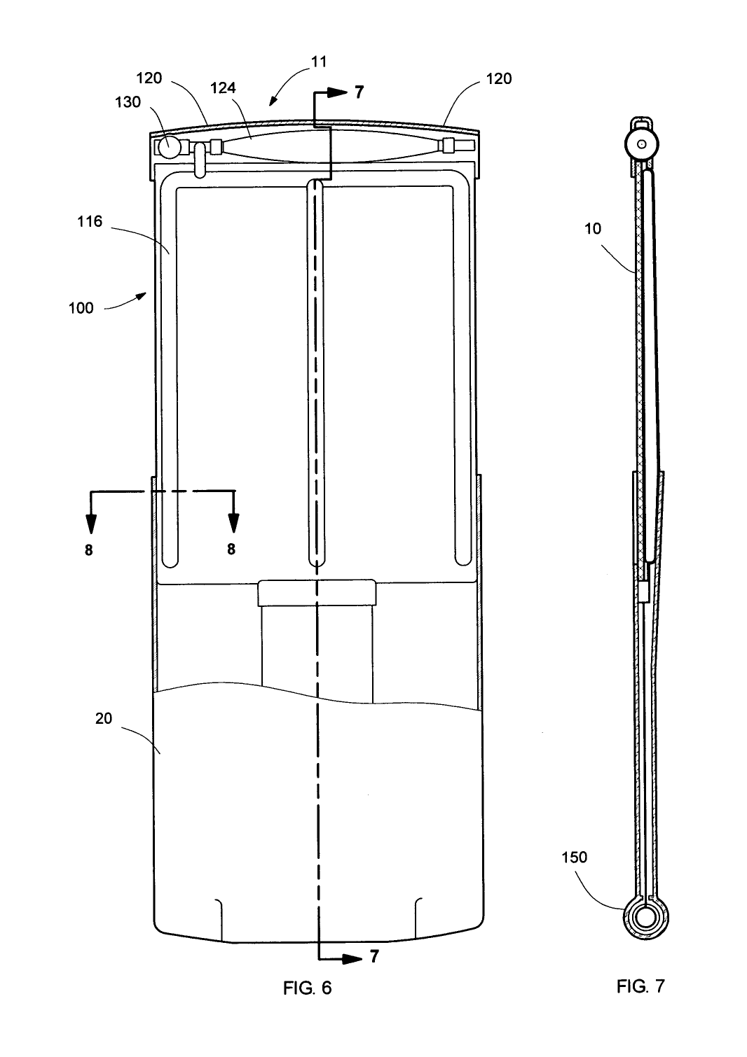

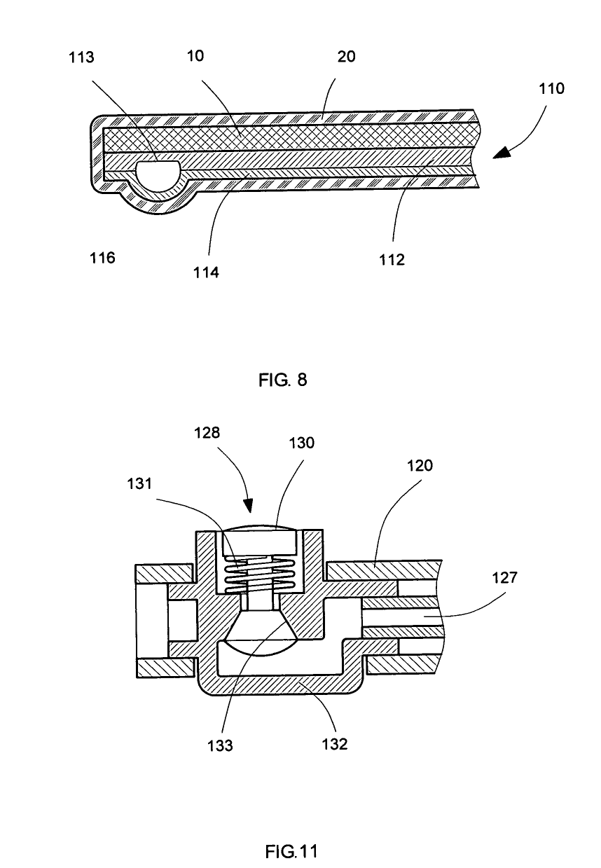

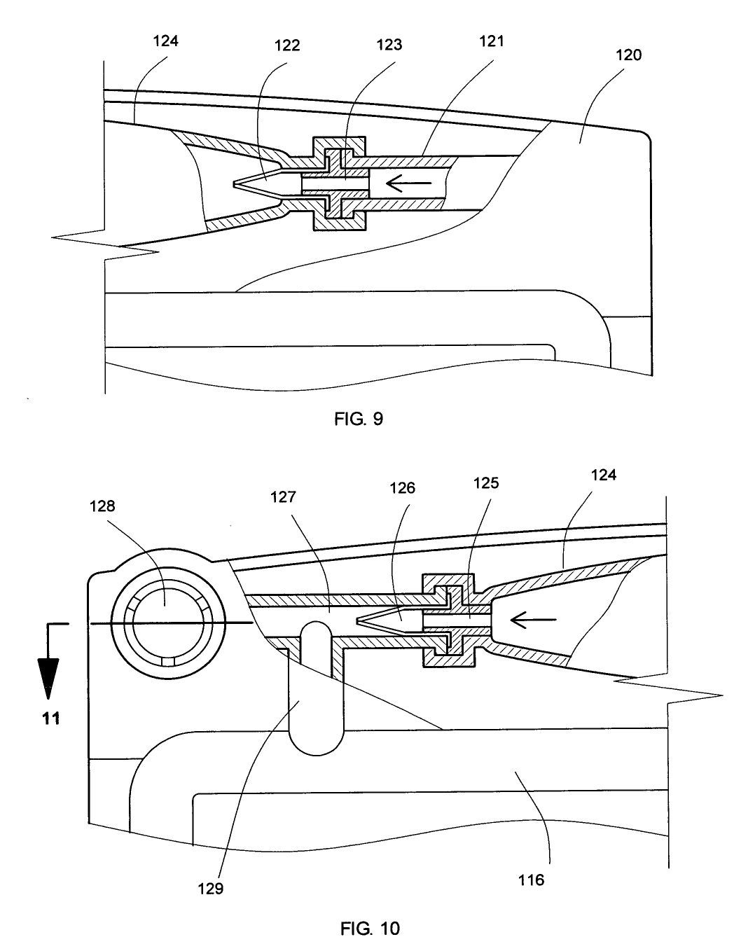

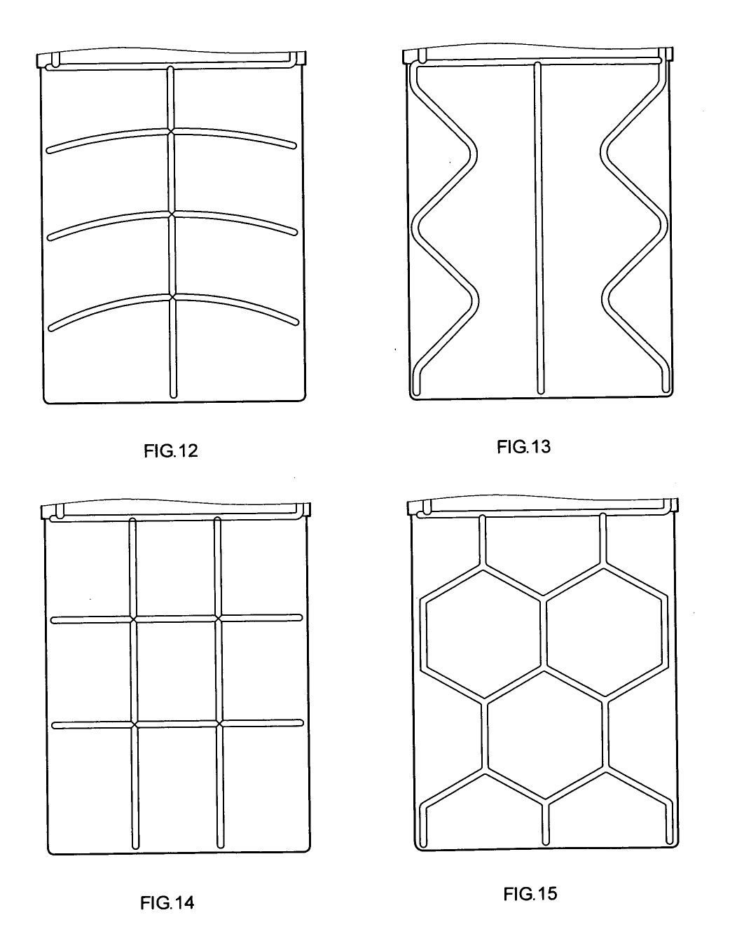

The Variable Stiffness Screen with Pneumatic Frame of the present invention is illustrated in FIGS. 1, 2, 3 and 4 (front and side views), FIG. 5 (front view with a broken out portion of the sleeve), FIG. 6 (rear view with a broken out portion of the sleeve), FIG. 7 (sectional view), FIG. 8 (sectional view), FIG. 9 (sectional view of a detail), FIG. 10 (sectional view of a detail), FIG. 11 (sectional view), FIGS. 12, 13, 14 and 15 (conduit patterns).

The screen 1 incorporates a flexible display 10 attached to a pneumatic frame 100 with a handle assembly 120 mounted on top of the screen The screen 1 is encased in a carrying member, either a flexible flat sleeve 20 or a rigid case 30. (FIGS. 1, 2, 3 and 4).

The flexible flat sleeve 20 functions as a casing jacket that protects the flexible display 10 (FIGS. 1, 2, 5, 6 and 7), and it also has an embedded connecting and controlling circuitry. The sleeve 20 has a rectangular opening 21 at the top to accommodate the display's 10 permanent viewable area. The screen's pullback winding mechanism 40 (FIGS. 5 and 7) is mounted inside at the bottom of the sleeve 20. The sleeve 20 is made from plastic, for instance silicon rubber, having a desirable combination of structural, electrical and tactile properties.

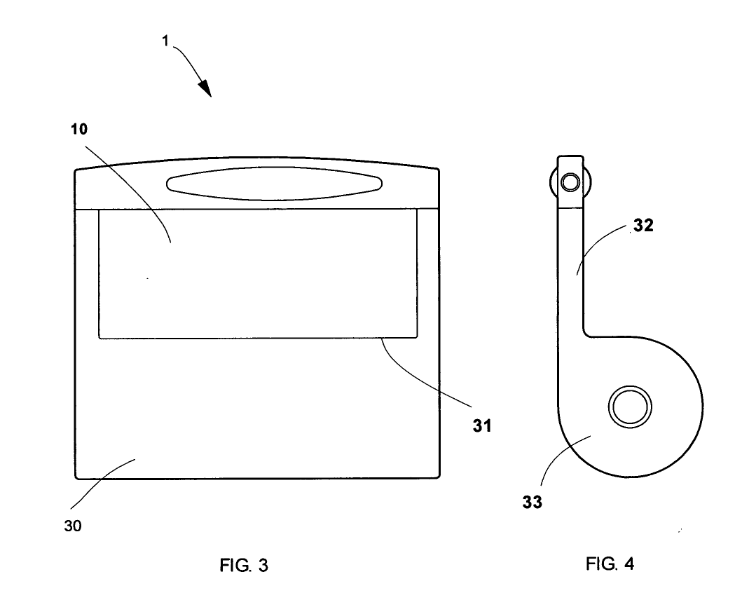

The case 30 houses the screen 10 (FIGS. 3, 4) and provides its connecting and controlling circuitry. The case 30 comprises a flat part 31 with a rectangular opening 32 revealing the display 10, and a cylindrical enclosure 33. The case 30 is made from a suitable rigid plastic.

The screen 1 functions in two working modes: closed and open. In a closed mode the screen 1 is pliable and placed inside the carrying member (FIGS. 1, 2, 3 and 4). The screen's upper part is exposed through the opening 21 in the carrying member thus creating the display's permanent viewable area. It allows for using of the screen 1, while it is folded or bent, when the volume of visual information is relatively low. In this mode a deactivated frame 100 is hidden inside the carrying member.

In an open mode the screen 1 is pulled out of the carrying member 20/30 and its entire viewable area can be used to display a high volume of visual information (FIGS. 5 and 6). An activated frame provides the necessary rigidity for the screen in this drawn-out position. The screen 1 returns to the closed mode by means of the winding mechanism 40, when the support system 100 is deactivated.

The pneumatic frame 100 provides the desirable transfer from flexibility to firmness to the display 10 depending on the pressure applied to the air inside the system's structural elements. It allows the flexible display 10 to be normally pliable and placed inside either the sleeve 20 or case 30, and when the frame is actuated, to be firm and rigid for having a pulled-out working position (FIGS. 5, 6, 7).

The pneumatic frame 100 comprises a conduits assembly 110 and a handle assembly 120 (FIG. 6, 7).

The conduits assembly 110 is composed of two pieces, the inner sheet 112 and the outer sheet 114 (FIG. 8) of an air-impervious elastomer, preferably urethane. Other similar lightweight, air-impervious, inflatable materials could readily be utilized. The inner sheet 112 is formed with a plurality of shallow grooves 113 serving as bottom portions of the screen's air inflatable tubular conduits (FIG. 12). Being bonded together in a predetermined manner, both pieces create a plurality of air inflatable tubular conduits 116. The conduits 116 communicate with each other and are heat-sealed along their perimeters.

The pattern and number of conduits can vary depending on the structural properties of a particular flexible display. The less firm and resilient a display is, the denser pattern of the supporting conduits should be used. For instance, the conduit configuration with one central vertical element and a few additional elements provides quick inflation of the conduits (FIGS. 12 and 13). The wafer and honeycomb configurations of the conduits allow for distribution of support to the display in a structurally even manner, thus providing a sufficient level of the screen's stiffness in its withdrawn mode (FIGS. 14 and 15).

The handle assembly 120 carries functional elements of the system: a miniature air pump 124, an intake check valve 122, an outlet check valve 126 and a release valve 130. The air pump 124 draws air through the intake tube 121, and communicates with the supporting conduits 116 through the connecting tube 128 (FIGS. 6, 9, 10).

The air pump 124 is a flexible, resilient ellipsoidal bulb. It is a one-piece element formed of a resilient elastomeric material such as rubber, natural or synthetic or a blend thereof The pump 124 is placed at the center of the handle 120 to serve two functions—inflation of the support conduits 116 and pulling of the flexible display 10 out of the sleeve 20 (FIG. 5, 6). The system's structural stability is achieved by sandwiching the upper part of the inflatable portion 110 with the pump and valves between two halves of the inverted U-shaped handle 120 (FIG. 7).

The check valves allow airflow in either direction. The check valves 122 and 126 are axially aligned on the opposite ends of the pump 124 and can vary in design and configuration. For instance, a conventional duckbill check valve is used for this purpose in both cases (FIGS. 10 and 11). The valves 122 and 126 themselves are formed of elastomeric material, preferably silicone, with a tubular body tapered to a flat at its output end. Under normal conditions, each valve is such as to preclude the flow of air there through. When, however, a pressure differential is generated on opposite sides thereof through the depression or release of the bulb, the check valves will open for the flow of air in one direction, as shown by the arrow. The intake check valve 122 is oriented to allow for the suction of air from the atmosphere to the pump 124. The outlet check valve 126 is placed to allow for the air passage from the pump 124 to the conduits 116. Upon the cessation of pumping, the check valves will close to preclude further movement of air there through. The valves are equipped with the corresponding adaptors 123 and 125 allowing for the proper attachment of the valves to the pump. The adaptors are preferably fabricated of a rigid material, aluminum, for instance, so that a secure coupling may be maintained.

The release valve 130 comprises a spring-loaded plunger 132 mounted in a fitting 134 having conically shaped aperture 135 (FIG. 11). The plunger's conical part mates to the aperture being urged inward by the coil spring 133. Therefore the release valve 130 is normally closed, precluding the loss of air from the conduits 116 through the aperture 135 into the atmosphere.

The operating state of the variable stiffness screen 1 of the present embodiment will now be explained. In order to withdraw the screen 1 the user grasps the screen's handle 120 and pulls the screen 1 from the carrying member against the action of the winding mechanism 30. When the display 10 is fully opened the user actuates the pneumatic frame 100 by depressing the pump 124.

Normally, the proposed combination of the check and release valves does not allow for the flow of air through the system. To actuate the system the user starts depressing and releasing the pump 124. When the pump 124 is depressed (for example, by squeezing the bulb between the thumb and index finger), the air volume inside the bulb decreases, thus raising the pressure inside. It forces the outlet check valve 126 to open and the excess air is pumped into the conduits 116. When the manual pressure on the bulb is reduced, it returns to its original position, the intake check valve 122 opens and the pump 124 is filled with air. This cycle is repeated until the conduits 116 are fully inflated with air. To make inflating more efficient, the bulb can be reinforced with a plate spring or the like.

After being inflated, the conduits 116 are expanded to serve as a frame for the display. Consequently, the entire screen 1 becomes firm and rigid for displaying the desirable amount of visual information. At the same time, it becomes substantially thicker than its carrying member, and it precludes the screen 1 from being pulled back by the urging means of the winding mechanism 40.

Using the release valve 130 deflates the frame. The user depresses the plunger 132 against the action of coil spring 133, thus connecting the inflated conduits 116 through the connecting tube 128 with the aperture 135. As a result, the excess air volume from the system escapes through the aperture 135 (FIG. 11). The system's air pressure equalizes to atmospheric pressure, and the screen 1 becomes pliable enough to be pulled back automatically by the winding mechanism 40.

In an alternative embodiment of the pneumatic frame, the air source may be a disposable gas cartridge (for instance, an O.sub.2 source) that contains a certain number of filling charges for inflating the conduits.

### CONCLUSION, RAMIFICATIONS, AND SCOPE

Accordingly, the reader will see that the variable stiffness screen's functional flexibility allows to create a desirable visual interface between the user and a wearable digital device, providing viewing ability of high-quality graphics and images comparable in the viewable size to that of a handheld's display, or even larger. This level of presentation of information is not achievable on cellular phones and wrist-worn devices by the existing means. invention. By providing the proposed flexible video interface it could transform the existing archetypes of wearable electronic devices into user-centered products that can adjust themselves rapidly to different requirements.

The proposed structural system allows for the variable stiffness screen to be used as a universal interface platform for the new generation of cellular phones and wireless terminals/PDA. It allows to fully utilize the great potential of the flexible display technology, regardless of a particular flexible display chosen by the manufacturer.

Although the description above contains much specificity, it should not be construed as limiting the scope of the invention, but as merely providing illustrations of some of the presently disclosed embodiments of this invention. Thus the scope of the invention should be determined by the appended claims and their legal equivalents, rather than by the examples given.

1. A variable stiffness screen comprising a flexible electronic display attached to a pneumatic frame and providing means for changing said screen's properties from flexibility to rigidity to make said display stiff and stable.

2. The screen of claim 1, further including a carrying member encasing said screen; wherein said screen functions in a closed position inside said carrying member and in an open position, where said display is fully visible to the user.

3. The screen of claim 2, wherein said screen is coupled to said carrying member by means of a pullback winding mechanism, which includes locking means allowing to secure said screen automatically in said open position.

4. The screen of claim 2, wherein said carrying member is a flexible flat sleeve having a rectangular opening revealing a respective part of said display, and incorporating an embedded electrical circuitry.

5. The screen of claim 2, wherein said carrying member is a rigid case comprising a flat part with said rectangular opening and an adjacent cylindrical enclosure housing a rolled-up part of said screen, and said case includes said embedded electrical circuitry.

6. The screen of claim 1, wherein said means for changing said screen's properties from flexibility to rigidity comprise a pneumatic frame.

7. The screen of claim 7, wherein said pneumatic frame includes a conduit assembly and a handle assembly.

8. The screen of claim 8, wherein said conduit assembly is formed of two air-impervious pieces bonded together in such a way as to create a plurality of sealed tubular conduits.

9. The screen of claim 8, wherein said handle assembly includes means for inflating and deflating said tubular conduits.

10. The screen of claim 10, wherein said means for inflating said tubular conduits include a pneumatic pump associated with check and release valves, all interrelated with each other and said interior chambers.
